(19) United States
(12) Patent Application Publication
(10) Pub. No.: US 2016/0298227 A1
(43) Pub. Date: Oct. 13, 2016

(54) A CRUCIBLE DEVICE USED IN COATING SYSTEM

(71) Applicant: SHENZHEN CHINA STAR OPTOELECTRONICS TECHNOLOGY CO., LTD, Shenzhen, Guangdong (CN)

(72) Inventors: Xindi ZHANG, Shenzhen, Guangdong (CN); Yung-Jui LEE, Shenzhen, Guangdong (CN)

(21) Appl. No.: 14/647,104

(22) PCT Filed: Jun. 27, 2014
(86) PCT No.: PCT/CN2014/080962

§ 371 Date: May 25, 2015

(30) Foreign Application Priority Data
Dec. 31, 2013 (CN) 201310753996.9

(51) Int. Cl. C23C 14/24; C23C 14/54

(52) U.S. Cl. CPC C23C 14/243; C23C 14/543

(57) ABSTRACT

The present invention discloses a crucible device used in coating system. The crucible device used in coating system comprise a barrel structure, a plurality of heaters, a crucible, a plurality of temperature sensors, and a plurality of driving means, the plurality of heaters are arranged in vertical direction in the barrel structure and used to heat the materials in the crucible, the plurality of temperature sensors are arranged in vertical direction in the crucible to measure the temperature inside the crucible, the plurality of driving means are used to drive at least one of the plurality of heaters to move in vertical direction so as to control the temperature inside the crucible. By this way, the evaporation rate can be controlled and stay stable.

### FIELD OF THE INVENTION

The present invention relates to a crucible device used in coating system.

### BACKGROUND OF THE INVENTION

In the thermal evaporation method, organic materials in the crucible used in coating system are heated in vacuum environment, sublimate type or melt type organic materials in the condition of high temperature are gasified, and deposited on the TFT structure or the substrate with anode structure. The evaporating temperature and the dissociation temperature of organic materials are close with each other, while the temperature difference inside the crucible is large; the evaporation rate is easy to become unstable.

### SUMMARY OF THE INVENTION

The present invention provides a crucible device used in coating system, which can make the evaporation rate stable.

The present invention is realized in such a way that: A crucible device used in coating system, the crucible device used in coating system comprising a barrel structure, a plurality of heaters, a crucible, a plurality of temperature sensors, and a plurality of driving means, the plurality of heaters are arranged in vertical direction in the barrel structure and used to heat the materials in the crucible, the plurality of temperature sensors are arranged in vertical direction in the crucible to measure the temperature inside the crucible, the plurality of driving means are used to drive at least one of the plurality of heaters to move in vertical direction so as to control the temperature inside the crucible.

Preferably, the plurality of heaters comprise electric heating wires wound on the inner wall of the barrel structure.

Preferably, the crucible is inside the barrel structure and the plurality of heaters are located between the outer wall of the crucible and the inner wall of the barrel structure.

Preferably, the arrangement density of the plurality of heaters is varied in vertical direction.

Preferably, the plurality of temperature sensors comprise a plurality of thermocouples disposed at different vertical areas of the crucible.

Preferably, the crucible has a heat insulation pad disposed at the bottom of the crucible.

Preferably, the crucible has a heat insulation cover disposed at the top of the crucible.

Preferably, the crucible comprises a conceiving portion and an exhaust portion, the conceiving portion is connected with the exhaust portion.

Preferably, the exhaust portion comprises one or more gas outlet.

The crucible device used in coating system according to any one of claim to, the plurality of driving means comprise a left driving means unit and a right driving means unit located respectively at the two sides of the barrel structure, the left driving means unit and the right driving means unit are disposed symmetrically.

Preferably, the plurality of driving means comprise at least twelve driving means.

Preferably, each driving means comprises a driving source and a transmission structure, the transmission structure is used to transmit the driving force of the driving source to the at least one of the plurality of heaters.

Preferably, the transmission structure comprises a lateral rod and a vertical rod, the lateral rod is connected with the driving source, and the lateral rod passes through the wall of the barrel structure and is connected with the vertical rod, the vertical rod is used to drive the at least one of the plurality of heaters to move in vertical direction.

According to the present invention, the crucible device used in coating system comprise a barrel structure, a plurality of heaters, a crucible, a plurality of temperature sensors, and a plurality of driving means, the plurality of heaters are arranged in vertical direction in the barrel structure and used to heat the materials in the crucible, the plurality of temperature sensors are arranged in vertical direction in the crucible to measure the temperature inside the crucible, the plurality of driving means are used to drive at least one of the plurality of heaters to move in vertical direction so as to control the temperature inside the crucible. By this way, the evaporation rate can be controlled and stay stable.

For more clearly and easily understanding above content of the present invention, the following text will take a preferred embodiment of the present invention with reference to the accompanying drawings for detail description as follows.

### BRIEF DESCRIPTION OF THE DRAWINGS

The drawings described herein are for illustration purposes only and are not intended to limit the scope of the present disclosure in any way.

FIG. 1 is a schematic sectional view of the crucible device used in coating system according to an embodiment of the present invention;

FIG. 2 is a schematic sectional view showing one arrangement of electric heating wires of the crucible device used in coating system; and

FIG. 3 is a schematic sectional view showing another arrangement of electric heating wires of the crucible device used in coating system.

### DETAILED DESCRIPTION OF THE PREFERRED EMBODIMENTS

The embodiments of the present invention will be described in detail with reference to the accompanying drawings.

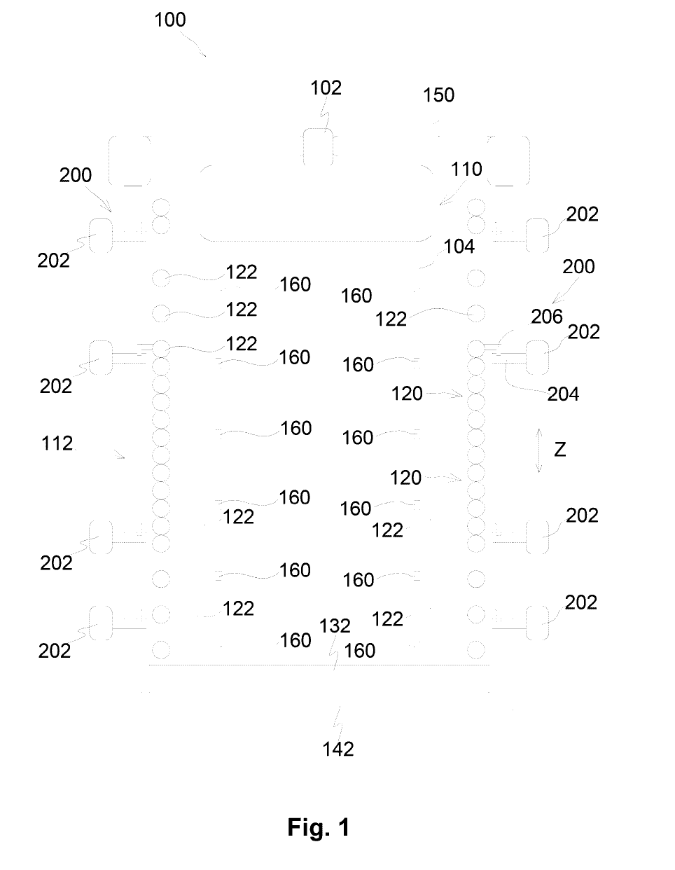

As shown in FIG. 1, the crucible device used in coating system 100 comprises a barrel structure 112, a plurality of heaters 120, a crucible 110, a plurality of temperature sensors 160, and a plurality of driving means 200. The plurality of heaters 120 are arranged in vertical direction Z in the barrel structure 112 and used to heat the materials in the crucible 110. The plurality of temperature sensors 160 are arranged in vertical direction Z in the crucible 110 to measure the temperature inside the crucible 110. The plurality of driving means 200 are used to drive at least one of the plurality of heaters 120 to move in vertical direction Z so as to control the temperature inside the crucible 110. By this way, the arrangement density of the plurality of heaters 120 can be changed as desired, such that the temperature inside the crucible 110 in vertical direction Z can be controlled as desired, and the evaporation rate stable can be kept stable.

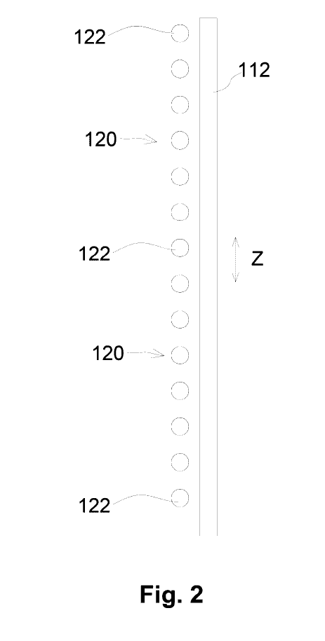

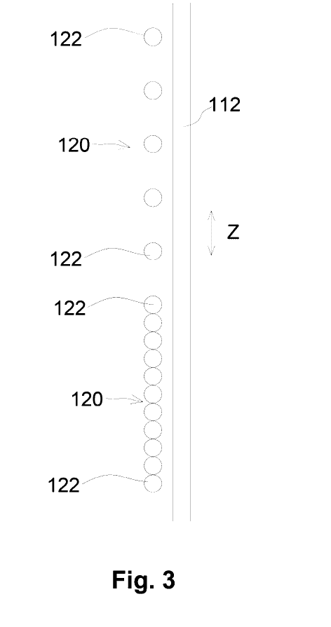

In the present embodiment, the plurality of heaters 120 comprise electric heating wires 122 wound on the inner wall of the barrel structure 112. Moreover, the crucible 110 is inside the barrel structure 112 and the plurality of heaters 120 are located between the outer wall of the crucible 110 and the inner wall of the barrel structure 112. As show in FIG. 1 to FIG. 3, the arrangement density of the plurality of heaters 120 is varied in vertical direction Z. In other words, the temperature inside the crucible 110 is determined by the arrangement density of the plurality of heaters 120. Usually the temperature is needed to rise from the bottom to the top of the crucible 110.

In addition, the crucible 110 has a heat insulation pad 132 disposed at the bottom of the crucible 110, and the crucible 110 has a heat insulation cover 150 disposed at the top of the crucible 110. The heat insulation pad 132 and the heat insulation cover 150 may be made from metal. The crucible 110 comprises a conceiving portion 104 and an exhaust portion, the conceiving portion 104 is connected with the exhaust portion. The exhaust portion comprises one outlet 102 or more gas outlet.

In the present embodiment, the plurality of temperature sensors 160 comprise a plurality of thermocouples disposed at different vertical areas of the crucible 110, so as to monitor the temperature inside the crucible 110.

As shown in FIG. 1, the plurality of driving means 200 comprise a left driving means unit and a right driving means unit located respectively at the two sides of the barrel structure 112. The left driving means unit and the right driving means unit are disposed symmetrically. The plurality of driving means 200 comprise at least twelve driving means. In other word, the left driving means comprise at least six driving means; the right driving means unit comprise at least six driving means.

In particular, each driving means 200 comprises a driving source 202 and a transmission structure. The transmission structure is used to transmit the driving force of the driving source 202 to the at least one of the plurality of heaters 120. The transmission structure comprises a lateral rod 204 and a vertical rod 206. The lateral rod 204 is connected with the driving source 202, and the lateral rod 204 passes through the wall of the barrel structure 112 and is connected with the vertical rod 206, the vertical rod 206 is used to drive the at least one of the plurality of heaters 120 to move in vertical direction Z.

In other embodiments of the present invention, a touch panel is provided. The touch panel is electrically connected with the plurality of temperature sensors 160. Moreover, the touch panel is electrically connected with the plurality of driving means 200. In this way, by touching the touch panel, the plurality of driving means 200 can be controlled based on the measurement outputs from the plurality of temperature sensors 160, so as to achieve a stable evaporation rate.

In addition, different materials have different evaporating temperature and dissociation temperature, so different materials needs different temperature difference inside the crucible. According to the present embodiment, from the bottom to the top of the crucible, several temperature difference in the range of 0° C.˜40° C. can be set, several modes can be set. For example, nine modes can be set at a 5° C. temperature difference. One of the modes can be selected based on the characteristics of the material on the touch panel. After the mode selection, the crucible is heated and the temperature rises from the bottom to the top of the crucible.

When sublimate type materials are heated to evaporate, in the case of the exhaust hole blocked, the temperature of the bottom zone and central zone inside the crucible are lowered. Moreover, with respect to the central zone, the temperature of the bottom zone drops more. Meanwhile, the temperature of the top zone inside the crucible is raised. The temperature at the top zone is higher than the temperature at the bottom zone, for example the temperature difference is about 40° C. The temperature at the top zone should be lower than the dissociation temperature of the material. By this way, the material blocked at the exhaust hole will evaporate. Materials at the bottom zone do not evaporate. When the evaporation rate drops and the material blocked at the exhaust hole burn out completely. Then the temperature of the bottom zone and central zone inside the crucible may be raised and back to normal state, the evaporation rate can be controlled to be stable.

When melt type materials are heated to evaporate, because of the existence of temperature difference, it is easy to generate bubbles or powder, which cause that it takes a long time to achieve a stable evaporation rate. In this case, the temperature of the bottom zone and central zone inside the crucible can be raised consistently, such that the temperature of the bottom zone and the temperature of the central zone are substantially same. Meanwhile the temperature at the top zone should be lower than the temperature of the central zone, for example the temperature difference is about 20° C.˜30° C. By this way, materials at different position in vertical direction melt at the same time substantially, such that it can be fast to achieve a stable evaporation rate.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A crucible device used in coating system, comprising a barrel structure, a plurality of heaters, a crucible, a plurality of temperature sensors, and a plurality of driving means, wherein the plurality of heaters are arranged in vertical direction in the barrel structure and used to heat the materials in the crucible, the plurality of temperature sensors are arranged in vertical direction in the crucible to measure the temperature inside the crucible, the plurality of driving means are used to drive at least one of the plurality of heaters to move in vertical direction so as to control the temperature inside the crucible.

2. The crucible device used in coating system of claim 1, wherein the plurality of heaters comprise electric heating wires wound on the inner wall of the barrel structure.

3. The crucible device used in coating system of claim 2, wherein the crucible is inside the barrel structure and the plurality of heaters are located between the outer wall of the crucible and the inner wall of the barrel structure.

4. The crucible device used in coating system of claim 3, wherein the arrangement density of the plurality of heaters is varied in vertical direction.

5. The crucible device used in coating system of claim 1, wherein the plurality of temperature sensors comprise a plurality of thermocouples disposed at different vertical areas of the crucible.

6. The crucible device used in coating system of claim 1, wherein the crucible has a heat insulation pad disposed at the bottom of the crucible.

7. The crucible device used in coating system of claim 1, wherein the crucible has a heat insulation cover disposed at the top of the crucible.

8. The crucible device used in coating system of claim 1, wherein the crucible comprises a conceiving portion and an exhaust portion, the conceiving portion is connected with the exhaust portion.

9. The crucible device used in coating system of claim 8, wherein the exhaust portion comprises one or more gas outlet.

10. The crucible device used in coating system of claim 1, wherein the plurality of driving means comprise a left driving means unit and a right driving means unit located respectively at the two sides of the barrel structure, the left driving means unit and the right driving means unit are disposed symmetrically.

11. The crucible device used in coating system of claim 10, wherein the plurality of driving means comprises at least twelve driving means.

12. The crucible device used in coating system of claim 11, wherein each driving means comprises a driving source and a transmission structure, the transmission structure is used to transmit the driving force of the driving source to the at least one of the plurality of heaters.

13. The crucible device used in coating system of claim 12, wherein the transmission structure comprises a lateral rod and a vertical rod, the lateral rod is connected with the driving source, and the lateral rod passes through the wall of the barrel structure and is connected with the vertical rod, the vertical rod is used to drive the at least one of the plurality of heaters to move in vertical direction.
